(19) United States
(12) Patent Application Publication
(10) Pub. No.: US 2014/0132282 A1
(43) Pub. Date: May 15, 2014

(54) DEVICE AND METHOD FOR EMI SOURCE LOCATION

(71) Applicant: Sverker Sander, Billdal (SE)

(72) Inventor: Sverker Sander, Billdal (SE)

(73) Assignee: Telefonaktiebolaget L M Ericsson (PUBL), Stockholm (SE)

(21) Appl. No.: 14/130,276

(22) PCT Filed: Jul. 1, 2011
(86) PCT No.: PCT/EP2011/061130

§ 371 Date: Dec. 30, 2013

(51) Int. Cl. G01R 31/00

(52) U.S. Cl. CPC G01R 31/002
USPC 324/613

(57) ABSTRACT

An electronics device, comprising one or more circuit boards and a plurality of power converters on one or more of said circuit boards, each power converter comprising one or more transducers for measuring a voltage or a current in the power converter, the electronics device additionally comprising a sub-system for locating sources of electromagnetic interference. The transducers of two or more of the power converters are also connected to the sub-system for locating sources of electromagnetic interference to supply it with measurement data. The sub-system for locating sources of electromagnetic interference is arranged to use the measurement data from the transducers in order to locate sources of electromagnetic interference.

### TECHNICAL FIELD

The present invention discloses an electronics device with the ability to locate sources of electromagnetic interference, and also discloses a corresponding method.

### BACKGROUND

Electromagnetic interference, EMI, may constitute a serious problem in an electronics device. Electromagnetic interference may cause the electronics device to malfunction, and may, in the case of the electromagnetic interference being generated internally, lead to the device being in non-compliance with requirements for electromagnetic compatibility, EMC. It is thus important to be able to locate sources of EMI.

Traditional methods for locating sources of EMI comprise measuring voltages or currents by manually connecting probes for such instruments as oscilloscopes and/or spectrum analyzers, or by measuring the electromagnetic field around an electronics device by connecting near field antenna probes to an oscilloscope or a spectrum analyzer.

As can be understood, the traditional methods for locating sources of EMI are work-intensive, and are also difficult to use in locations which are difficult to access manually.

### SUMMARY

It is an object of the invention to obviate at least some of the disadvantages of the traditional methods for locating sources of EMI in and around an electronics device.

This object is addressed by the invention in that it discloses an electronics device comprising one or more circuit boards, and a plurality of power converters arranged on one or more of the circuit boards. Each power converter comprises one or more transducers for measuring a voltage or a current in the power converter.

The electronics device additionally comprises a sub-system for locating sources of electromagnetic interference. In the electronics device, the transducers of two or more of the power converters are also connected to the sub-system for locating sources of electromagnetic interference in order to supply it with measurement data, and the sub-system for locating sources of electromagnetic interference is arranged to use the measurement data from the transducers in order to locate sources of electromagnetic interference.

Thus, since the electronics device of the invention utilizes transducers of power converters which are already present in the electronics device, a large degree of simplification is achieved, as well as obtaining cost-efficiency. In addition, the difficulties of manually accessing measuring points in an electronics device are also obviated by means of the invention.

In embodiments of the electronics device, the power converters use Analogue to Digital Converters, ADCs, as their transducers.

In embodiments of the electronics device, the measured voltage or current in the power converter is also used as an output voltage or current from the power converter.

In embodiments of the electronics device, at least one of the power converters is a DC-DC converter.

In embodiments of the electronics device, at least one of said power converters is an AC-DC converter.

In embodiments of the electronics device, at least one of said power converters is an AC-AC converter.

In embodiments of the electronics device, the transducers are arranged to continuously supply the measurement data to the sub-system for locating sources of electromagnetic interference.

In embodiments of the electronics device, the transducers are arranged to supply a time limited segment of said measurement data at discrete points in time to the sub-system for locating sources of electromagnetic interference. In some such embodiments of the electronics device, the sub-system for locating sources of electromagnetic interference is arranged to control the discrete points in time at which the transducers supply said measurement data.

In embodiments of the electronics device, the transducers are arranged to include a timestamp with each time limited segment of measurement data, signifying when the measurement was made.

In embodiments, the electronics device is equipped with a list of where the transducers are located in the electronics device, for use in locating sources of electromagnetic interference.

In embodiments, the electronics device is equipped with a list of how power terminals of the power converters are electrically connected to each other, for use in locating sources of electromagnetic interference.

In embodiments of the electronics device, the location of a source of electromagnetic interference is determined by weighing amplitude signals in said measurement data by their corresponding transducer's location.

The invention also discloses a method for use in an electronics device, comprising receiving measurement data on voltage and/or current from one or more transducers in one or more power converters on one or more circuit boards in the electronics device. According to the method, the measurement data is used in order to locate sources of electromagnetic interference.

In embodiments of the method, the power converters use Analogue to Digital Converters as their transducers.

In embodiments of the method, at least one of the power converters is a DC-DC converter.

In embodiments of the method, at least one of the power converters is an AC-DC converter.

In embodiments of the method, at least one of the power converters is an AC-AC converter.

In embodiments of the method, the measurement data is continuously supplied from said transducers.

In embodiments of the method, the measurement data is supplied during a time limited segment at discrete points in time.

In embodiments of the method, a timestamp is included from the transducers with each time limited segment of measurement data, signifying when the measurement was made.

In embodiments of the method, a timestamp is attached to each received measurement data.

In embodiments of the method, the locations of the transducers in the electronics device are used for locating sources of electromagnetic interference.

### BRIEF DESCRIPTION OF THE DRAWINGS

The invention will be described in more detail in the following, with reference to the appended drawings, in which

FIGS. 1 and 2 show embodiments of a power converter, and

FIGS. 3-5 show examples of electronic devices with multiple power converters, and

FIG. 6 shows a schematic block diagram of a sub-system for locating sources of electromagnetic interference, and

FIG. 7 shows a principle for use in the invention, and

FIG. 8 shows a flowchart of a method.

### DETAILED DESCRIPTION

Embodiments of the present invention will be described more fully hereinafter with reference to the accompanying drawings, in which embodiments of the invention are shown. The invention may, however, be embodied in many different forms and should not be construed as being limited to the embodiments set forth herein. Like numbers in the drawings refer to like elements throughout.

The terminology used herein is for the purpose of describing particular embodiments only, and is not intended to limit the invention.

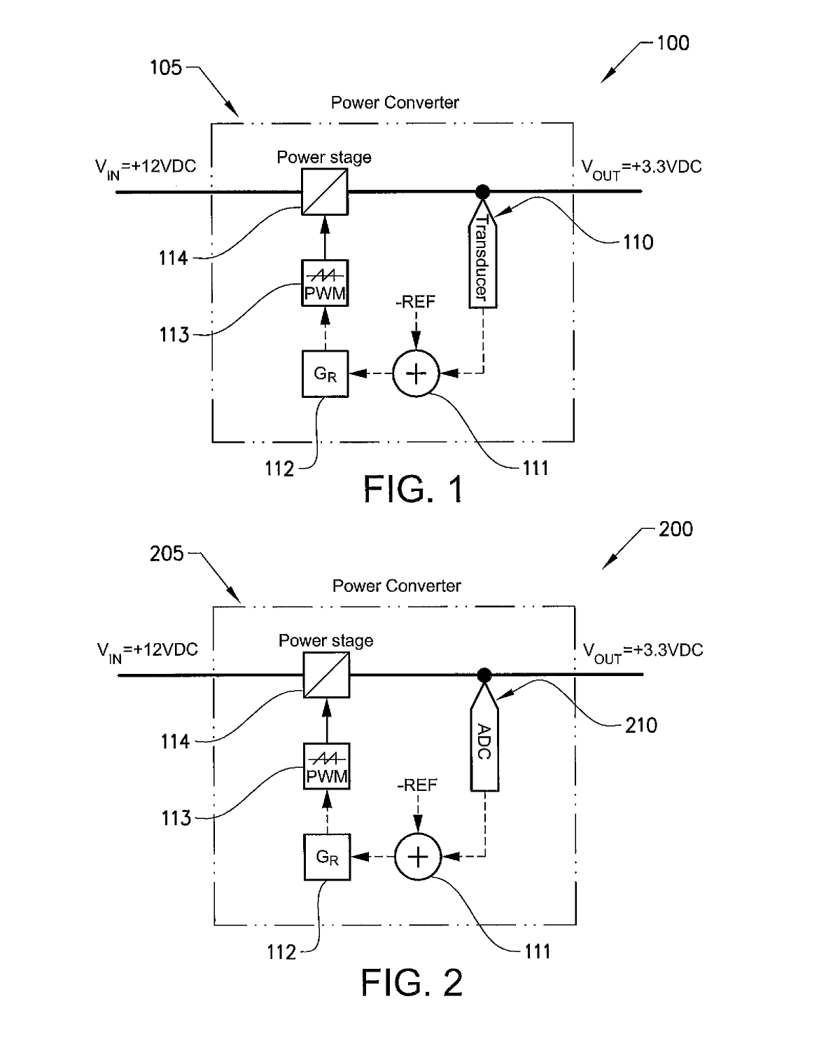

As mentioned initially in this text, the electronics device utilizes a plurality of power converters. For this reason, a power converter will be briefly described with reference to FIGS. 1 and 2. The power converter shown in those two figs is a DC-DC converter, which is however merely one example of a power converter which can be used in the electronics device of the invention. Other kinds of power converters which can be used in the invention include AC-DC converters and AC-AC converters.

Thus, FIG. 1 shows an embodiment of a power converter 105 for use in an electronics device. The power converter comprises a transducer 110 for measuring a voltage or a current in the power converter 105. This voltage or current is, for example, either an internal voltage or current in the power converter, or it can be a voltage or current which is produced in the power converter and then used as an output voltage or current from the power converter. The latter is the case in the embodiment 105 shown in FIG. 1, i.e. the transducer 110 measures a voltage which is used as output voltage V_{OUT} from the power converter 105. In the example of FIG. 1, the transducer 110 is part of a control loop in the power converter 105, and thus outputs its measured values to a comparator 111, which compares the value measured by the transducer 110 to an accurate reference value shown as REF in FIG. 1. The difference between the transducer's measured value and the accurate reference value is used by a regulator G_{R} 112 whose output signal is then used by a Pulse Width Modulator, PWM 113, and a power stage 114.

In embodiments, one of which is shown in FIG. 2, the transducer 110 is an Analogue to Digital Converter, an ADC, 210.

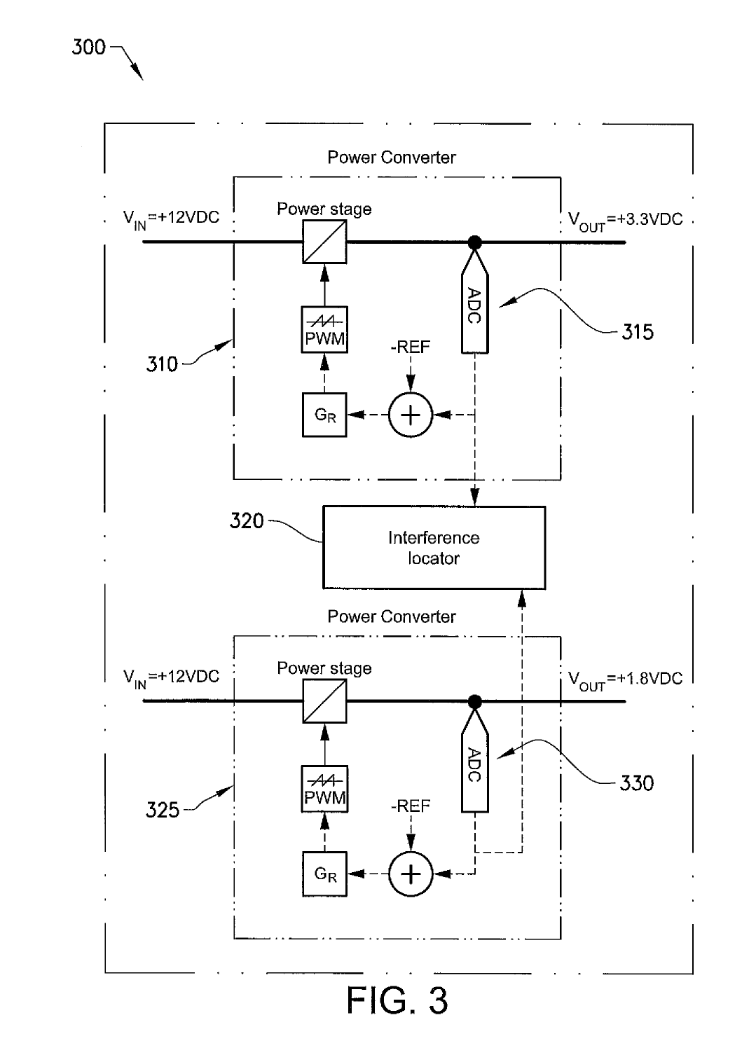

FIG. 3 shows a first embodiment of an electronics device 300 of the invention. The embodiment 300 is a Printed Circuit Board, a PCB, which is one embodiment of the electronics device. The electronics device can also consist of or comprise two or more PCBs which are connected to each other

The PCB 300 comprises a number of power converters, two of which, 310, 325, are shown in FIG. 3. Again, the power converters are shown as DC-DC converters, but this is merely one embodiment of a power converter which may be used in the electronics device. In addition, some of the components of the power converters 310, 325 are shown in FIG. 3, although they are not referenced by reference numbers nor are they commented upon further here.

The electronics device also comprises a sub-system for locating sources of electromagnetic interference, in FIG. 3 shown as an interference locator 320. The interference locator 320 is in FIG. 3 shown as being located on the PCB 300, but it can in other embodiments also be a unit which is separate from the PCB 300, but connected to it.

The interference locator 320 is arranged to receive measurement data from the transducers 315, 330 of the power converters 310, 325. It should be pointed out that the measurement data which is received by the interference locator 320 is in most embodiments the “normal” measurement data from the transducers 315, 330, i.e. the measurements made by the transducers 315, 330 in their “normal” function in the power converters 310, 325, which makes the invention highly cost-efficient. An example of such a “normal” function for a transducer in a power converter is in a feedback loop which maintains a constant output voltage from the power converter.

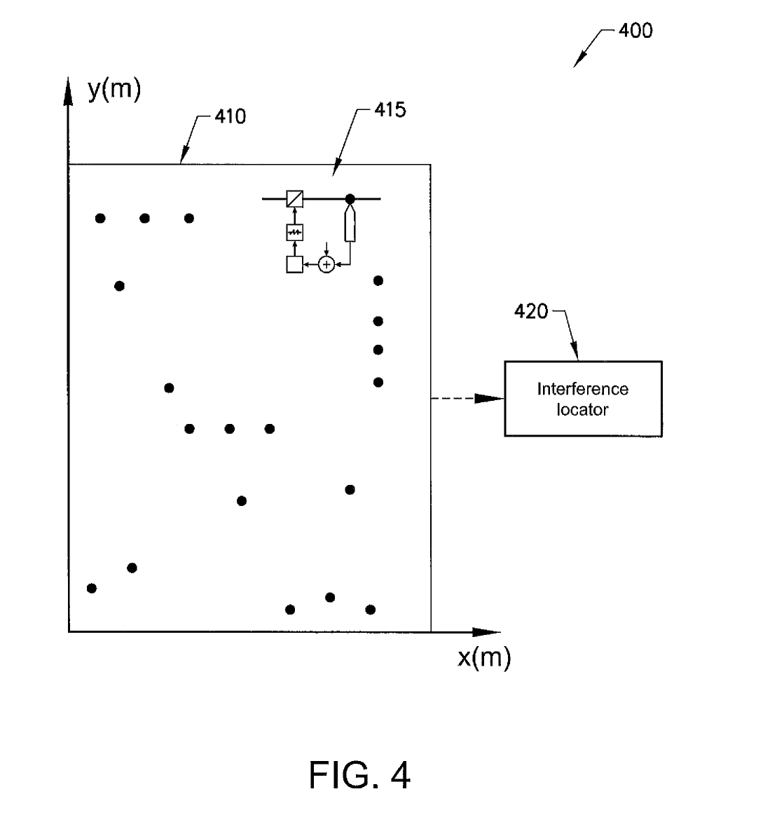

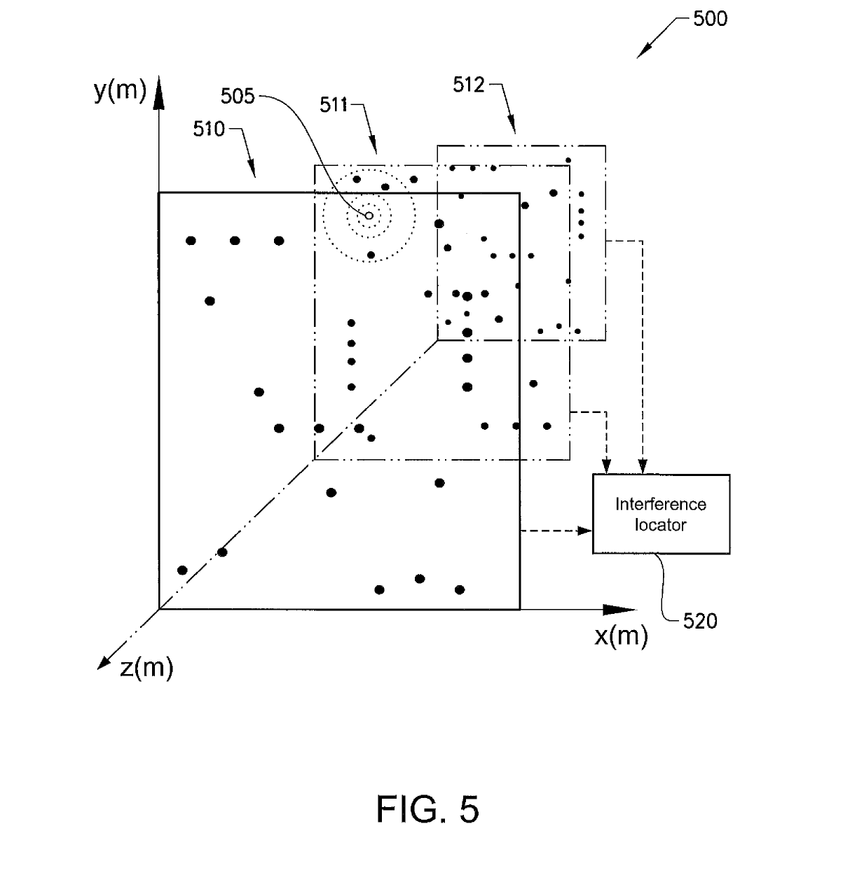

The interference locator 320 is arranged to use the measurement data from the transducers 315, 330 in order to locate sources of EMI, electromagnetic interference which are external or internal inside to the PCB 300. As realized by now by those skilled in the field, the exact mechanism used by the interference locator 320 in order to locate sources of EMI can vary between a large number of such mechanisms, some of which will be exemplified in this text. However, before such mechanisms are described, some further embodiments of the electronics device will be given, with reference to FIGS. 4 and 5.

FIG. 4 shows an embodiment of an electronics device 400 with a PCB 410, which is shown in FIG. 4 with a number of dots on it, with each dot representing one transducer connected to a power converter on the PCB 410, so that each dot also represents one transducer. The PCB 410 has twenty dots on it, which is a realistic example, due to the increasing number of power converters on present day PCBs. This is another feature which adds to the invention's usefulness: present day PCBs or other electronics devices usually have a large number of power converters, each of which has a transducer which can also be used as a transducer in an EMI locator. In FIG. 4, one of the power converters, shown as 415, has been drawn in its entirety, in order to show what the dots in the PCB 410 in FIG. 4 signify.

The electronics device 400 also comprises an interference locator 420, which receives measurement data from the transducers of the power converters on the PCB 410. In FIG. 4, the PCB 410 is drawn against an orthogonal x-y coordinate system, so that each transducer or dot in the PCB 410 can be assigned an unambiguous position with x-y coordinates. These coordinates are suitably either stored in the interference locator 420 initially, or they can, alternatively, be reported from the transducers along with the measurement data. The coordinates of a reporting transducer are suitably used by the interference locator when locating a source of EMI.

FIG. 5 shows another embodiment of an electronics device 500. The electronics device 500 is shown as comprising three PCBs 510, 511, 512, which in this particular embodiment are arranged in parallel to each other. As indicated by means of dots on the PCBs 510, 511 and 512, each PCB incorporates a number of power converters, each of which has a transducer. The electronics device 500 also comprises an interference locator 520, here shown as being separate from the electronics device 500, but connected to it. In similarity to the embodiment of FIG. 4, the interference locator 520 either has the locations in the coordinate system x-y-z of each transducer stored initially, or the positions can be reported by the transducers continuously when reporting measured data, or once only.

In addition, FIG. 5 also shows a source of EMI 505, in FIG. 5 symbolically shown as a circle (as opposed to dots) with a number of concentric dashed rings around it, in order to symbolize the propagation of the EMI from the source of EMI 505.

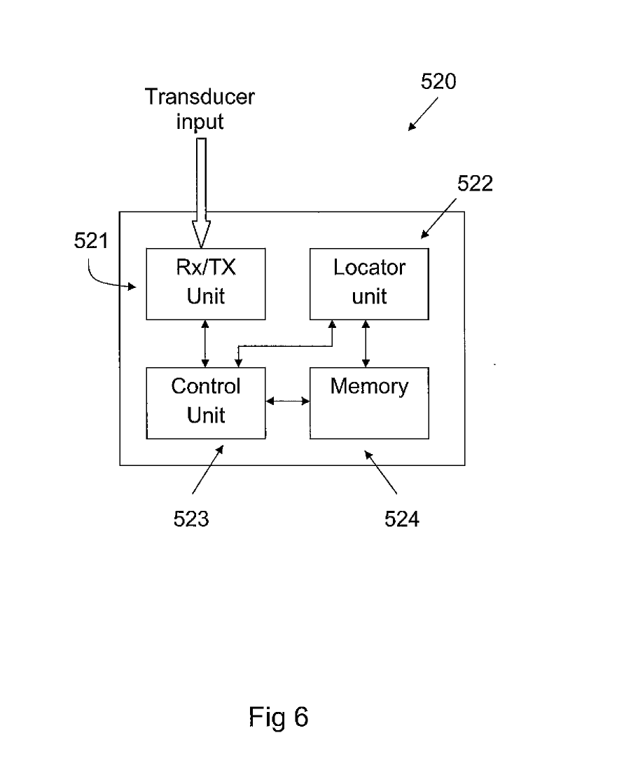

Turning now to an example of the nature of the interference locator 320, 420, 520 of FIGS. 3-5, an example of such an embodiment is shown in FIG. 6. The interference locator shown in FIG. 6 is labeled 520, but can equally well serve as the interference locator 320 or 420 of the embodiments of FIG. 3 or 4.

As shown in FIG. 6, the interference locator 520 comprises a communications unit, shown as Rx/Tx unit 521. The communications unit 521 is the unit that receives the measurement data from the transducers of the power converters, and is also the unit that transmits commands etc to the transducers in those embodiments in which the transducers are arranged to be controlled by the interference locator 520. The interference locator 520 also comprises a control unit 523, which is the unit that controls the function of the interference locator 520, i.e. it controls the function of the other units of the interference locator 520. The interference locator 520 also comprises a memory unit 524, which can, for example, be used in order to store measurement data from the transducers of the power converters, and/or to store program code for the function of the control unit 523 etc.

In addition, the interference locator 520 also comprises a locator unit 522, which is the unit that processes the measurement data from the transducers of the power converters in order to locate sources of EMI, by means of e.g. determining the most likely location of sources of EMI.

In FIG. 6, the communications unit 521 is shown as being connected to the control unit 523. In such an embodiment, the control unit 523 forwards measurement data from the transducers of the power converters to the locator unit 522, while, in other embodiments, the communications unit can also be connected directly to both the control unit 523 and to the locator unit 522, as well as to the memory unit 524.

Regarding the measurement data which is supplied by the transducers of the power converters to the interference locator 520, in some embodiments of the electronics device, the transducers are arranged to continuously supply their measurement data to the interference locator 520, while, in other embodiments, the transducers are arranged to supply a time limited segment of measurement data at discrete points in time to the interference locator 520. In such embodiments, the transducers can, for example, be arranged to supply measurement data during a one second interval every minute. In some embodiments, the transducers are arranged to include a timestamp with each such time limited segment of measurement data, signifying when the measurement was made. In some embodiments, as mentioned, the measurement data supplied by the transducers is stored in the memory unit 524 for processing by the locator unit 522.

In other embodiments, the interference locator 520 is arranged to control the discrete points in time at which the transducers supply their measurement data, for example in order to decrease the real time data transmitted on a data bus Naturally, in such embodiments as well, the transducers may be arranged to include a timestamp with their measurement data, signifying when the measurement was made, and the measurement data supplied by the transducers may be stored in the memory unit 524 for processing by the locator unit 522.

As mentioned, the locator unit is arranged to process measurement data in order to locate sources of EMI. In order to facilitate this, in some embodiments, the interference locator 520, suitably by means of the memory unit 524, is supplied with a list of where the transducers of the power converters are located in the electronics device, suitably by means of coordinate systems such as those shown in FIGS. 4 and 5.

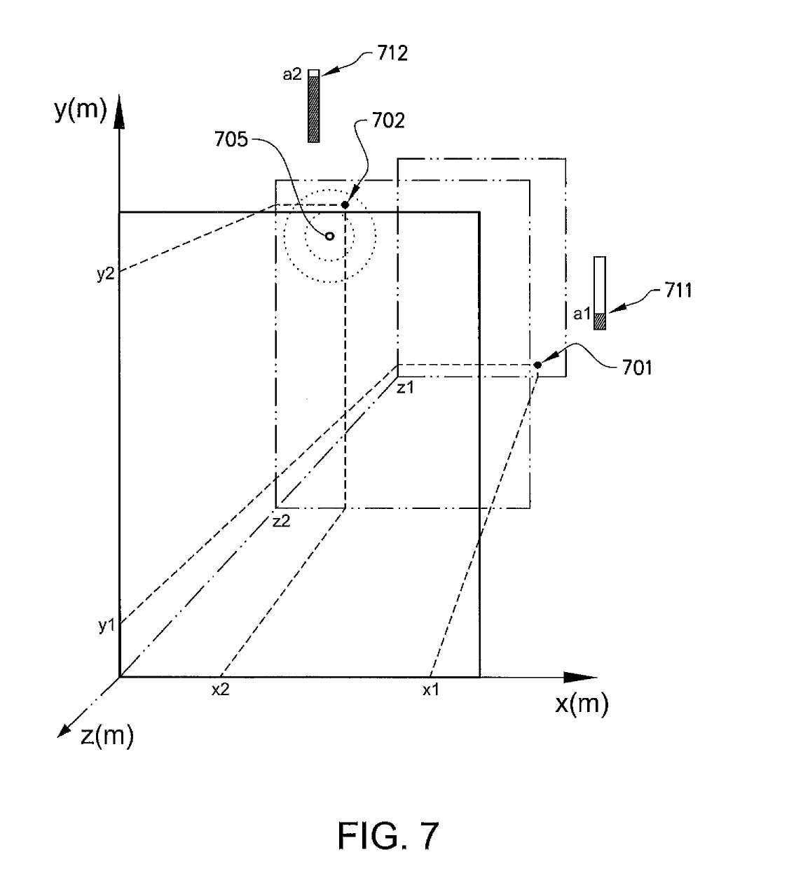

Turning now to how the location of sources of EMI are located by the locator unit 522 by means of the measurement data, an example of a principle will now be given with reference to FIG. 7. Those skilled in the art will realize that a wide variety of such mechanisms and principles are possible within the scope of the invention.

FIG. 7 shows an example of a situation with two transducers 701, 702. The transducers are symbolically shown as dots in order to indicate their location in the coordinate system x-y-z, which was also shown in FIG. 5. Each transducer has a location defined by a set of x-y-z coordinates in the coordinate system. In FIG. 7, there is also shown an EMI source 705, indicated as a dot symbolically surrounded by rings, in order to show the interfering radiated emissions from the EMI source 705. The EMI source 705 also has a location which is determined by a set of x-y-z coordinates in the coordinate system, and these coordinates are what the interference locator 520 is arranged to determine, or least to approximate it as accurately as possible.

With reference to the example shown in FIG. 7, an EMI source such as the one 705 is located by the interference locator 520 in that it is arranged to determine the x-y-z coordinates of the EMI source 705 by weighing the amplitude of the signals in the measurement data by the location of the measurement data's corresponding transducer's, i.e. the positions in the x-y-z coordinate system of the transducers 701, 702.

The transducers 701, 702 will detect different interference signal amplitudes at a certain signal frequency. The different signal amplitudes are represented by level meters 711, 712 shown next to the transducers in FIG. 7. The x-y-z coordinates of the EMI source 705 can, for example, be determined by the interference locator 520 by multiplying each signal amplitude a₁, a₂ by the corresponding coordinates of the transducers 701, 702 along the x, y or z-axis, independently, i.e. one multiplication for each transducer and coordinate. In order to illustrate this concept, the procedure for determining the x-coordinate of the EMI source 705 will now be described: The x-coordinate of the EMI source 705 is determined by multiplying each signal amplitude a₁, a₂ by the x-coordinate x₁, x₂ of corresponding transducer 701, 702. The sum of the products is then divided by the sum of the signal amplitudes a₁+a₂ in order to determine the x-coordinate of the EM source 705. The same procedure is carried out for the y and z-axis, in order to find the coordinates along those axes' for the EMI source 705. A general expression for this procedure is as follows:

$$\overline{x} = \frac{1}{a} {\sum }_{i}^{ } {a}_{i} {x}_{i} ; a = {\sum }_{i}^{ } {a}_{i}$$

$$\overline{y} = \frac{1}{a} {\sum }_{i}^{ } {a}_{i} {y}_{i} ; a = {\sum }_{i}^{ } {a}_{i}$$

$$\overline{z} = \frac{1}{a} {\sum }_{i}^{ } {a}_{i} {z}_{i} ; a = {\sum }_{i}^{ } {a}_{i}$$

where x̅, y̅ and z̅ represent the values for the determined coordinates along each axis x, y, z for the EMI source 705, and xᵢ, yᵢ and zᵢ represent the coordinates for transducer i along the x-, y- and z-axis, respectively, and aᵢ is the amplitude of the signal from transducer i.

In embodiments, the electronics device is also equipped with a list of how power terminals of the power converters are electrically connected to each other, for use in locating sources of electromagnetic interference. This is useful since interference from an EMI source can propagate through conductors (CE, Conducted Emission) as well as through air (RE, Radiated Emission). In the case of CE, information about how and if the power converters are connected to each other is useful, for example by information on how their power terminals are connected to each other.

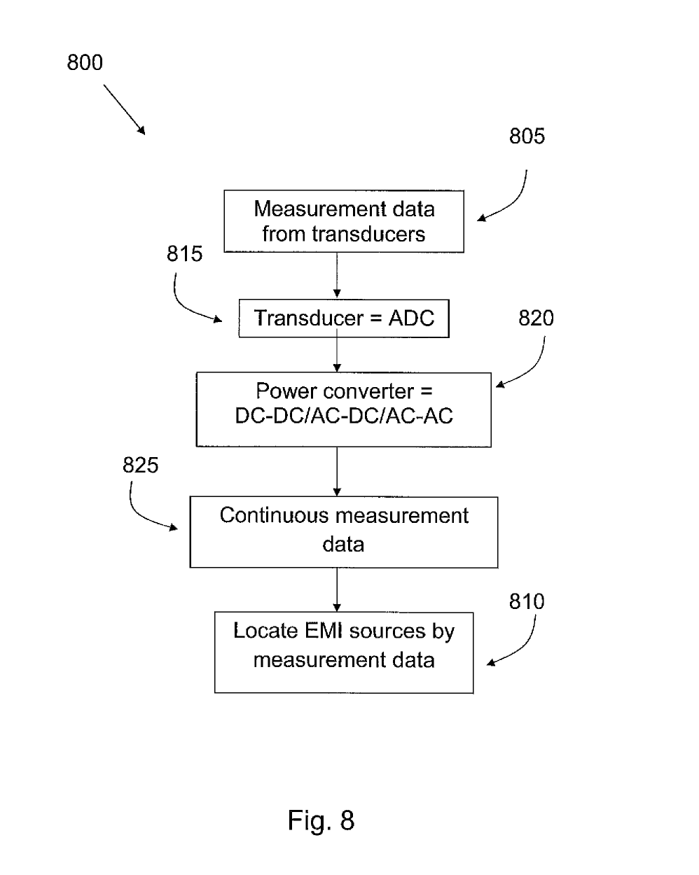

FIG. 8 shows a schematic flowchart of a method 800. The method 800 is for use in an electronics device, and comprises, step 805, receiving measurement data on voltage and/or current from one or more transducers in one or more power converters on one or more circuit boards in the electronics device. According to the method 800, the measurement data is used in order to locate, step 810, sources of electromagnetic interference.

According to embodiments of the method 800, as shown in step 815, the power converters use Analogue to Digital Converters, ADCs as their transducers.

According to embodiments of the method 800, as shown in step 820, at least one of the power converters is a DC-DC converter.

According to embodiments of the method 800, as shown in step 820, at least one of the power converters is an AC-DC converter.

According to embodiments of the method 800, as shown in step 820, at least one of the power converters is an AC-AC converter.

According to embodiments of the method 800, as shown in step 825, the measurement data is continuously supplied from the transducers.

According to embodiments of the method 800, the measurement data is supplied during a time limited segment at discrete points in time.

According to embodiments of the method 800, a timestamp is included from the transducers with each time limited segment of measurement data, signifying when the measurement was made.

According to embodiments of the method 800, a timestamp is attached to each received measurement data.

According to embodiments of the method 800, the locations of the transducers in the electronics device are used for locating sources of electromagnetic interference.

Once a source of EMI has been located by a device or method as described above, the EMI source's location can either be transmitted to another unit in the same system or in another system, or it can be displayed on a display which is connected to the device.

The location of an EMI source is suitably activated by an operator who has noticed that there is a high likelihood of a source of EMI being present. Naturally, the “search” for a source of EMI can also yield a zero result, which is then communicated in the manner described above.

Embodiments of the invention are described with reference to the drawings, such as block diagrams and/or flowcharts. It is understood that several blocks of the block diagrams and/or flowchart illustrations, and combinations of blocks in the block diagrams and/or flowchart illustrations, can be implemented by computer program instructions. Such computer program instructions may be provided to a processor of a general purpose computer, a special purpose computer and/or other programmable data processing apparatus to produce a machine, such that the instructions, which execute via the processor of the computer and/or other programmable data processing apparatus, create means for implementing the functions/acts specified in the block diagrams and/or flowchart block or blocks.

These computer program instructions may also be stored in a computer-readable memory that can direct a computer or other programmable data processing apparatus to function in a particular manner, such that the instructions stored in the computer-readable memory produce an article of manufacture including instructions which implement the function/act specified in the block diagrams and/or flowchart block or blocks.

The computer program instructions may also be loaded onto a computer or other programmable data processing apparatus to cause a series of operational steps to be performed on the computer or other programmable apparatus to produce a computer-implemented process such that the instructions which execute on the computer or other programmable apparatus provide steps for implementing the functions/acts specified in the block diagrams and/or flowchart block or blocks.

In some implementations, the functions or steps noted in the blocks may occur out of the order noted in the operational illustrations. For example, two blocks shown in succession may in fact be executed substantially concurrently or the blocks may sometimes be executed in the reverse order, depending upon the functionality/acts involved.

In the drawings and specification, there have been disclosed exemplary embodiments of the invention. However, many variations and modifications can be made to these embodiments without substantially departing from the principles of the present invention. Accordingly, although specific terms are employed, they are used in a generic and descriptive sense only and not for purposes of limitation.

The invention is not limited to the examples of embodiments described above and shown in the drawings, but may be freely varied within the scope of the appended claims.

1. An electronics device, comprising: one or more circuit boards; a plurality of power converters arranged on one or more of said circuit boards, each power converter, comprising one or more transducers for measuring a voltage or a current in the power converter; and a sub-system for locating sources of electromagnetic interference, wherein the transducers of two or more of the power converters are connected to the sub-system for locating sources of electromagnetic interference to supply the sub-system with measurement data, and the sub-system for locating sources of electromagnetic interference is arranged to use the measurement data from the transducers in order to locate sources of electromagnetic interference.

2. The electronics device of claim 1, in which the power converters use Analogue to Digital Converters as their transducers.

3. The electronics device of claim 1, in which said measured voltage or current in the power converter is also used as an output voltage or current from the power converter.

4. The electronics device of claim 1, in which at least one of said power converters is a DC-DC converter.

5. The electronics device of claim 1, in which at least one of said power converters is an AC-DC converter.

6. The electronics device of claim 1, in which at least one of said power converters is an AC-AC converter.

7. The electronics device of claim 1, in which the transducers are arranged to continuously supply said measurement data to the sub-system for locating sources of electromagnetic interference.

8. The electronics device of claim 1, in which the transducers are arranged to supply a time limited segment of said measurement data at discrete points in time to the sub-system for locating sources of electromagnetic interference.

9. The electronics device of claim 1, in which the transducers are arranged to include a timestamp with each time limited segment of measurement data, signifying when the measurement was made.

10. The electronic device of claim 7, in which the sub-system for locating sources of electromagnetic interference is arranged to control the discrete points in time at which the transducers supply said measurement data.

11. The electronics device of claim 1, further comprising a list of where the transducers are located in the electronics device for use in locating sources of electromagnetic interference.

12. The electronics device of claim 1, further comprising a list of how power terminals of the power converters are electrically connected to each other, for use in locating sources of electromagnetic interference.

13. The electronics device of claim 1, in which the location of an artificial interference center is determined by weighing amplitude signals in said measurement data by their corresponding transducer's location in the electronics device.

14. A method for use in an electronics device, comprising: receiving measurement data on voltage and/or current from one or more transducers in one or more power converters on one or more circuit boards in the electronics device; and using the measurement data in order to locate sources of electromagnetic interference.

15. The method of claim 14, wherein the power converters use Analogue to Digital Converters as their transducers.

16. The method of claim 14, wherein at least one of said power converters is a DC-DC converter.

17. The method of claim 14, wherein at least one of said power converters is an AC-DC converter.

18. The method of claim 14, wherein at least one of said power converters is an AC-AC converter.

19. The method of claim 14, wherein said measurement data is continuously supplied from said transducers.

20. The method of claim 14, wherein said measurement data is supplied during a time limited segment at discrete points in time.

21. The method of claim 14, wherein a timestamp is included from the transducers with each time limited segment of measurement data, signifying when the measurement was made.

22. The method of claim 14, wherein the locations of the transducers in the electronics device are used for locating sources of electromagnetic interference.
